(19) United States
(12) Patent Application Publication
(10) Pub. No.: US 2006/0028802 A1
(43) Pub. Date: Feb. 9, 2006

(54) Object storage devices, systems, and related methods

(75) Inventors: Christopher M. Shaw, San Diego, CA (US); Robert Charles Downs, La Jolla, CA (US)

Correspondence Address: QUINE INTELLECTUAL PROPERTY LAW GROUP, P.C., P O BOX 458, ALAMEDA, CA, 94501, US

(73) Assignee: IRM, LLC, Hamilton (BM)

(21) Appl. No.: 11/198,022

(22) Filed: Aug. 3, 2005

Related U.S. Application Data
(60) Provisional application No. 60/598,929, filed on Aug. 4, 2004.

(51) Int. Cl. H05K 7/00

(52) U.S. Cl. 361/728

(57) ABSTRACT

The present invention provides modular object storage devices that include object storage modules and support elements that include object storage module receiving areas that are structured to receive the object storage modules. The modular object storage devices also include position adjustment components that are structured to move the object storage modules into contact with elevated alignment surfaces of the object storage module receiving areas to align the object storage module in desired positions. The invention also provides systems and related methods of positioning object storage modules.

### CROSS-REFERENCES TO RELATED APPLICATIONS

This application claims the benefit of U.S. Provisional Application No. 60/598,929, filed Aug. 4, 2004, the disclosure of which is incorporated by reference in its entirety for all purposes.

### FIELD OF THE INVENTION

The present invention relates generally to the storage of objects and to the positioning of object storage devices. In certain embodiments, for example, the invention provides modular object storage devices having support elements relative to which removable object storage modules are accurately and precisely positioned.

### BACKGROUND OF THE INVENTION

The storage of objects in an organized manner that facilitates ready access to the objects is significant in a wide variety of contexts. To take one example, many modern scientific endeavors involve large numbers of processes performed in parallel to enhance throughput among other reasons. These processes include, inter alia, combinatorial chemical syntheses, protein crystallization screens, cell culture-based assays, and nucleic acid sequencing reactions. Multi-well containers, such as micro-well plates or reaction blocks, are commonly used in performing various steps in these processes and in storing the resultant product libraries pending subsequent access for additional processing or analysis. The storage and management of libraries in these types of objects can be highly complex.

Multi-well containers are commonly stored in “hotels,” which typically include housings that have multiple, vertically stacked shelves. Each shelf is generally structured to support one or more multi-well containers. To automate the processing of libraries stored in multi-well containers, robotic translocation devices are often used to move these objects between hotel shelves and given processing stations. The positioning of multi-well container hotels relative to these robotic translocation devices generally has a very low locating tolerance or tolerance for misalignment, as errors in the relative positioning of these devices may lead to damaged hotels, multi-well containers, and/or robotic devices when they unintentionally contact one another during operation. Moreover, certain multi-well container hotels have modular designs, which permit multiple containers supported on the shelves of the hotels to be transported simultaneously when a given hotel module is moved manually or otherwise. Thus, each time these movable modular hotels are re-positioned relative to robotic translocation devices in these systems, the positioning should be within the relevant alignment tolerances of the devices to minimize the risk of subsequent damage to components of the system. Furthermore, in addition to repeatedly positioning these modular hotels with sufficient accuracy, it is typically desirable that these hotel positioning processes be accomplished at rates that do not appreciably impact the throughput of the overall process being untaken.

Many pre-existing approaches to positioning or aligning object storage modules, such as multi-well container storage modules, lack adequate positioning accuracy, and/or efficiency. Therefore, it is apparent that there is a substantial need for devices, systems, and related methods of positioning object storage modules, consistently, accurately, and rapidly. These and a variety of additional features of the present invention will be evident upon a complete review of the following disclosure.

### SUMMARY OF THE INVENTION

The present invention provides object storage devices that include object storage modules that can be rapidly, accurately, and reliably positioned or located relative to support elements of the devices. Objects are typically supported on shelves of the object storage modules. In systems that include the object storage devices of the invention, the accurately positioned object storage modules minimize the risk of system components being damaged, e.g., when robotic gripping mechanisms grasp objects, such as multi-well containers, substrates, or the like supported on the shelves of the object storage modules. The invention also provides methods of positioning or locating these object storage modules relative to, e.g., substantially fixed support elements.

In one aspect, the invention provides a modular object storage device that includes at least one object storage module including at least one shelf that is structured to support at least one object. For example, the shelf is optionally structured to support at least one container (e.g., a multi-well plate, a multi-well reaction block, etc.) and/or at least one substrate (e.g., a silicon wafer, a solid support comprising arrayed molecules, or the like). Typically, the object storage module includes a housing having multiple, vertically stacked shelves, e.g., in the form of a hotel. The modular object storage device also includes a support element comprising at least one object storage module receiving area that is structured to receive the object storage module. The object storage module receiving area includes at least one set of at least three elevated alignment surfaces that together substantially correspond to at least a portion of a contour of the object storage module. The contour of the object storage module optionally includes a shape selected from, e.g., a regular n-sided polygon, an irregular n-sided polygon, a triangle, a square, a rectangle, a trapezoid, a circle, an oval, a portion thereof, or the like. In addition, the modular object storage device also includes at least one position adjustment component that is attached or attachable to the object storage module and the support element. The position adjustment component is structured to move the object storage module into contact with each of the elevated alignment surfaces, thereby positioning or locating the object storage module in a desired position (e.g., accurately aligned relative to an automated object translocation component, etc.). In certain embodiments, the modular object storage device includes multiple object storage modules, e.g., for increased storage capacity.

To illustrate, positions of the object storage module along at least two translational axes (e.g., X- and Y-axes) are determined when the object storage module is moved into contact with the elevated alignment surfaces. The elevated alignment surfaces are typically disposed on one or more surfaces of the object storage module receiving area. For example, the object storage module receiving area generally includes at least two sides in which a first side includes at least two elevated alignment surfaces of the set, and a second side includes at least one elevated alignment surface of the set. Typically, the object storage module receiving area includes multiple sets of at least three elevated alignment surfaces. In certain embodiments, the elevated alignment surfaces include datum pads.

The support element includes various embodiments. For example, the support element generally includes at least one frame component that at least partially defines the object storage module receiving area. Typically, the position of a support element is substantially fixed relative to another item, such as a robotic gripping apparatus or the like. In some embodiments, the support element includes a curved shape. Optionally, the support element is rotatable. In certain embodiments, the support element includes multiple object storage module receiving areas.

In some embodiments, the portion of the contour of the object storage module that substantially corresponds to the set of elevated alignment surfaces forms about a 90° angle. In these embodiments, the position adjustment component is typically attached or attachable to the object storage module and the support element such that the position adjustment component substantially bisects the 90° angle. Optionally, multiple position adjustment components are attached or attachable to the object storage module and the support element. In some embodiments, the position adjustment component is automated, whereas in others, the position adjustment component is manually operated. Typically, the position adjustment component modifies (e.g., reduces, compensates for, etc.) one or more defects in a structure of the object storage module when the object storage module is aligned relative to the support element. In some embodiments, the position adjustment component comprises at least one keeper plate and at least one latch body.

To further illustrate, the position adjustment component optionally includes at least one male fastening element and at least two female fastening elements. In these embodiments, the object storage module and the support element each generally include at least one of the female fastening elements. In addition, holes are typically disposed at least partially through the female fastening elements, which holes are structured to receive the male fastening element to effect contact between the object storage module and the elevated alignment surfaces of the object storage module receiving area when the male fastening element is disposed in the holes. Typically, the male fastening element includes a bolt, and the hole disposed at least partially through at least one of the female fastening elements includes threads that correspond to the threads disposed on the bolt.

In another aspect, the invention provides a system that includes at least one modular object storage device. The modular object storage device includes at least one object storage module comprising at least one shelf that is structured to support at least one object (e.g., at least one container, at least one substrate, etc.), and a support element comprising at least one object storage module receiving area that is structured to receive the object storage module. The object storage module receiving area comprises at least one set of at least three elevated alignment surfaces that together substantially correspond to at least a portion of a contour of the object storage module. The modular object storage device also includes at least one position adjustment component that is attached or attachable to the object storage module and the support element. The position adjustment component is structured to move the object storage module into contact with each of the elevated alignment surfaces to position the object storage module in a desired position. In certain embodiments, the position adjustment component is automated. In addition, the system also includes at least one object translocation component that is automated in some embodiments. The object translocation component is configured to translocate one or more objects to and/or from the shelf, and/or one or more object storage modules to and/or from one or more object storage module receiving areas of the support element. For example, the object translocation component optionally includes at least one robotic gripping apparatus.

The system of the invention includes various embodiments. To illustrate, the system optionally includes one or more of: at least one controller, at least one thermal modulation component, at least one material transfer component, or at least one detection component. The controller is configured to effect operation of one or more components of the system. The thermal modulation component is configured to modulate a temperature in and/or proximal to at least one other component of the system. In certain embodiments, at least a portion of at least one of the components of the system is housed in the thermal modulation component. The material transfer component is configured to transfer one or more materials to and/or from one or more objects. The detection component is configured to detect one or more detectable signals produced by one or more materials disposed in and/or taken from one or more objects.

In still another aspect, the invention provides a method of positioning an object storage module. The method includes moving the object storage module (e.g., using at least one position adjustment component) into contact with at least three elevated alignment surfaces that together substantially correspond to at least a portion of a contour of the object storage module. The object storage module includes at least one shelf that is structured to position at least one object. In some embodiments, the method includes translocating one or more objects to and/or from the shelf of the object storage module.

### BRIEF DESCRIPTION OF THE DRAWINGS

FIG. 1A schematically shows a modular object storage device from a front elevational view according to one embodiment of the invention.

FIG. 1B schematically shows the modular object storage device of FIG. 1A from a partially exploded perspective view.

FIG. 2A schematically illustrates an object storage module from a front elevational view according to one embodiment of the invention.

FIG. 2B schematically depicts the object storage module of FIG. 2A from a side elevational view.

FIG. 2C schematically shows the object storage module of FIG. 2A from a perspective view.

FIG. 3A schematically illustrates a support element from a front elevational view according to one embodiment of the invention.

FIG. 3B schematically illustrates the support element of FIG. 3A from a back elevational view.

FIG. 3C schematically shows the support element of FIG. 3A from a top view.

FIG. 3D schematically depicts the support element of FIG. 3A from a bottom view.

FIG. 3E schematically shows the support element of FIG. 3A from a rear perspective view.

FIG. 3F schematically shows a detailed perspective view of a portion of the support element of FIG. 3E.

FIG. 3G schematically illustrates a frame component of the support element of FIG. 3A from a top view.

FIG. 3H schematically illustrates the frame component of FIG. 3G from a front elevational view.

FIG. 3I schematically depicts a detailed perspective view of a portion of the frame component of FIG. 3G.

FIG. 3J schematically shows a detailed top view of a portion of the frame component of FIG. 3G.

FIG. 3K schematically depicts a detailed top view of a segment of the frame component portion of FIG. 3J.

FIG. 4A schematically shows a rotatable support element from a side elevational view according to one embodiment of the invention.

FIG. 4B schematically depicts the rotatable support element of FIG. 4A from a partially exploded perspective view.

FIG. 5A schematically illustrates a position adjustment component that includes male and female fastening elements from a top perspective view according to one embodiment of the invention.

FIG. 5B schematically shows the position adjustment component of FIG. 5A from a side perspective view.

FIG. 6A schematically depicts a position adjustment component that includes a keeper plate and a latch body from a top perspective view according to one embodiment of the invention.

FIG. 6B schematically shows the position adjustment component of FIG. 6A from a side perspective view.

FIG. 7A schematically depicts an automated position adjustment component from a top perspective view according to one embodiment of the invention.

FIG. 7B schematically shows the position adjustment component of FIG. 7A from a side perspective view.

FIG. 8 schematically illustrates a system that includes a modular object storage device and an automated container translocation component from a perspective view according to one embodiment of the invention.

FIG. 9 is a block diagram showing a representative logic device in which various aspects of the invention may be embodied.

FIG. 10A schematically depicts an object storage module located in an object storage module receiving area according to one embodiment of the invention.

FIG. 10B schematically shows the object storage module of FIG. 10A moved into contact with three elevated alignment surfaces of the object storage module receiving area of FIG. 10A.

### DETAILED DESCRIPTION

I. Definitions

Before describing the present invention in detail, it is to be understood that this invention is not limited to particular embodiments. It is also to be understood that the terminology used herein is for the purpose of describing particular embodiments only, and is not intended to be limiting. Units, prefixes, and symbols are denoted in the forms suggested by the International System of Units (SI), unless specified otherwise. Numeric ranges are inclusive of the numbers defining the range. Further, unless defined otherwise, all technical and scientific terms used herein have the same meaning as commonly understood by one of ordinary skill in the art to which the invention pertains. The terms defined below, and grammatical variants thereof, are more fully defined by reference to the specification in its entirety.

The term “aligned” refers to a positioning or state of adjustment of two or more items in relation to each other. In certain embodiments, for example, an object storage module and a support element are aligned as intended relative to one another when each of the elevated alignment surfaces of the particular object storage module receiving area of the support element in which the object storage module is positioned contact the object storage module.

The term “attachable” in the context of two or more items refers to items, which are capable of being attached to one another.

The term “attached” in the context of two or more items refers to an association between the items in which the items are fixedly or removably contacted or mated directly or indirectly with one another. In certain embodiments of the invention, for example, position adjustment components, or portions thereof, are removably mated with object storage modules and support elements.

The term “automated” refers to a process, device, or system that is controlled at least in part by mechanical or electronic devices in lieu of direct human control. For example, the systems of the invention include automated translation components that are configured to translocate one or more items, such as multi-well containers, substrates, object storage modules, and the like.

The term “bisects” refers to the division of something into two at least approximately equal parts. In some embodiments, for example, position adjustment components divide 90° angles formed by portions of object storage module contours into approximately equal angles (i.e., two angles of about 45° each).

The term “bottom” refers to the lowest point, level, surface, or part of a device or system, or device or system component, when oriented for typical designed or intended operational use.

The term “contour” refers to an outline or shape that a perimeter of an item forms. To illustrate, exemplary contours of object storage modules optionally include, e.g., regular n-sided polygons, irregular n-sided polygons, triangles, squares, rectangles, trapezoids, circles, ovals, portions thereof, or the like.

The term “correspond” in the context of elements or components of a device or system refers to elements or components that are structured to function together with one another. For example, elevated alignment surfaces are structured to contact or mate with at least portions of object storage module contours such that the object storage modules can be located in desired positions. To further illustrate, male fastening elements optionally comprise bolts and female fastening elements optionally comprise threads that are structured to receive the threads of the bolts.

The phrase “defects in a structure of the object storage module” refers to imperfections in the structure of the object storage module that prevent the object storage module from being aligned relative to a support element without an applied force. In certain embodiments, for example, position adjustment component are used to apply forces to align object storage modules relative to support elements.

The term “defines” in the context of two or more items or elements refers a property in which at least a first item or element delineates, fixes, or marks the limits of at least a portion of a second item or element. In some embodiments, for example, support elements include frame components that delineate at least portions of object storage module receiving areas.

The term “determined” in the context of two or more items refers a state in which the position or location of at least one of the items, or a portion thereof, is substantially fixed relative to at least one other item, or a portion thereof. To illustrate, the positions of an object storage module along at least two translational axes are substantially fixed when the object storage module is moved into contact with the elevated alignment surfaces of an object storage module receiving area in certain embodiments of the invention.

The term “elevated” in the context of at least two surfaces refers to a state in which at least one of the surfaces is raised relative to at least one other surface. In some embodiments of the invention, for example, alignment surfaces are raised (e.g., extend from, etc.) relative to other surfaces of frame components.

The term “set” refers to a collection of two or more items. Typically, the items form a structural component or otherwise function together. To illustrate, object storage module receiving areas generally include at least one set of at least three elevated alignment surfaces that together substantially correspond at least a portion of a contour of an object storage module of a modular object storage device of the invention.

The term “substantially” refers to an approximation. In certain embodiments, for example, sets of elevated alignment surfaces at least approximately correspond to at least portions of object storage module contours. To further illustrate, at least portions of object storage module contours form 90° angles that are at least approximately bisected by position adjustment components in some embodiments of the invention.

The term “top” refers to the highest point, level, surface, or part of a device or system, or device or system component, when oriented for typical designed or intended operational use, such as positioning object storage modules, storing objects, and/or the like.

The term “translational axes” refers to three linear axes (i.e., X-, Y-, and Z-axes) in a three-dimensional rectangular coordinate system. The “X-axis” is substantially parallel to a horizontal plane and approximately perpendicular to both the Y- and Z-axes. The “Y-axis” is substantially parallel to a horizontal plane and approximately perpendicular to both the X- and Z-axes. The “Z-axis” is substantially parallel to a vertical plane and approximately perpendicular to both the X- and Y-axes.

II. Introduction

While the present invention will be described with reference to a few specific embodiments, the description is illustrative of the invention and is not to be construed as limiting the invention. Various modifications can be made to the embodiments of the invention described herein by those skilled in the art without departing from the true scope of the invention as defined by the appended claims. For example, although the storage of multi-well containers (e.g., multi-well plates, multi-well reaction blocks, etc.) is emphasized herein primarily for clarity of illustration, it will be appreciated that the devices, systems, and methods of the invention can be adapted for the storage of essentially any object. It is also noted here that for a better understanding, certain like components are designated by like reference letters and/or numerals throughout the various figures.

In overview, the present invention relates to modular object storage devices in which object storage modules may be accurately and efficiently positioned relative to support elements of the devices. Object storage modules typically include housings that have multiple, vertically stacked shelves that are each structured to support one or more objects, such as containers, substrates, etc. The modular designs of these devices permits the transport of selected subsets of objects stored on the shelves of given device modules such that those subsets can be, e.g., individually processed or analyzed. In addition to the flexibility provided by these designs, modules are easily positioned in proper alignment with, e.g., automated translocation components, such as robotic gripping apparatus. The proper alignment of robotic gripping apparatus with object storage devices is important, as misalignment often leads to damaged devices and/or objects due to unintentional contact between storage devices, objects, and/or gripping devices.

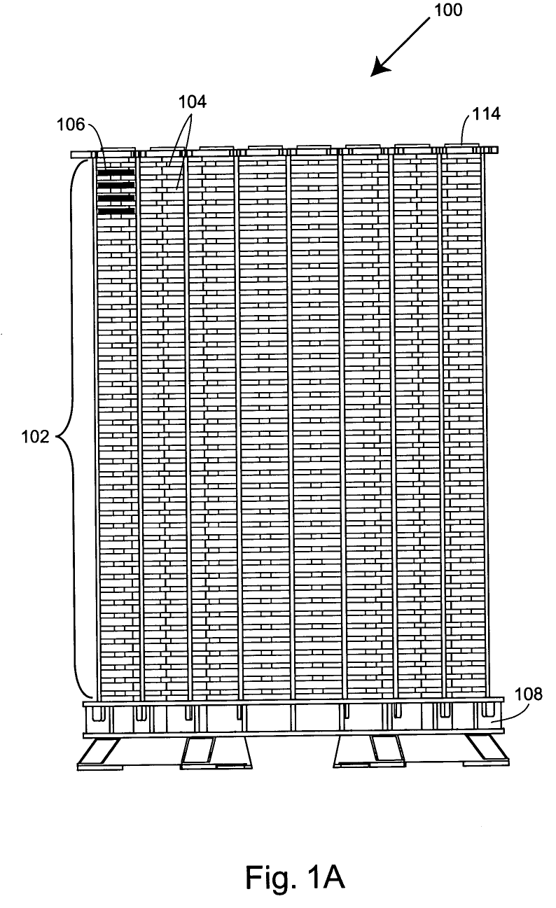

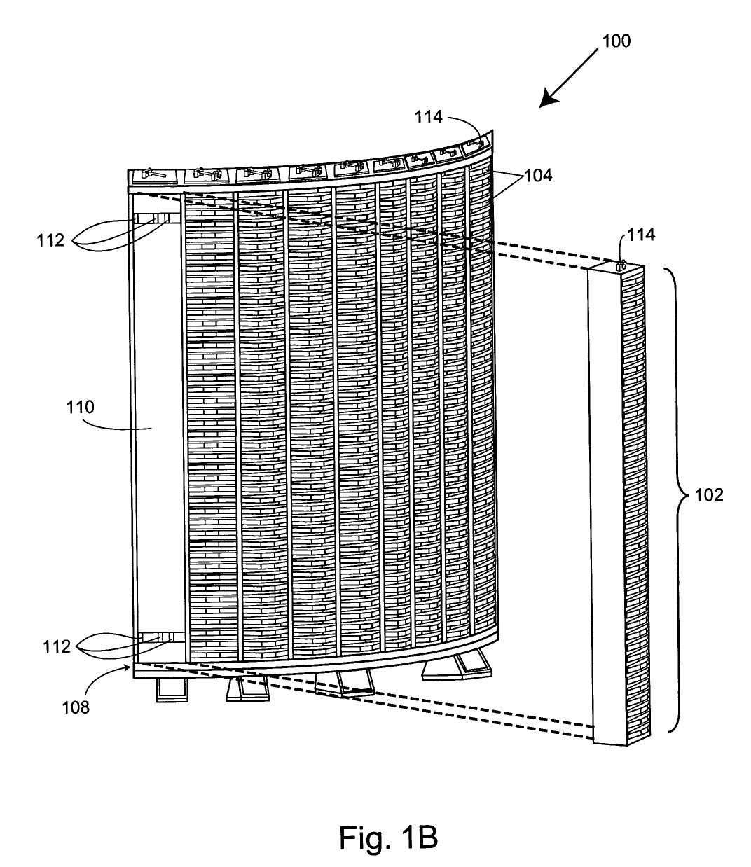

Referring initially to FIGS. 1 A and B, modular object storage device 100 is schematically illustrated from front elevational and partially exploded perspective views, respectively, according to one embodiment of the invention. As shown, modular object storage device 100 includes multiple object storage modules 102 that each include multiple, vertically stacked shelves 104. In the embodiment shown, each shelf 104 is structured to support one multi-well plate 106. As also shown, modular object storage device 100 includes support element 108, which includes object storage module receiving areas 110. Object storage module receiving areas 110 are each structured to receive one object storage module 102. Further, object storage module receiving areas 110 each include sets of three elevated alignment surfaces 112. Each set of three elevated alignment surfaces 112 together substantially corresponds to at least a portion of the contour (shown as having a partial rectangular shape) of object storage module 102. In addition, object storage module 102 also includes position adjustment component 114 that is attached or attachable to object storage module 102 and support element 108. Position adjustment component 114 is structured to move object storage module 102 into contact with each of the elevated alignment surfaces to locate or position object storage module 102 in a desired position (e.g., accurately aligned relative to an automated object translocation component, etc.).

Each of the components of the modular object storage devices of the invention is described in greater detail below, including object storage device component fabrication. In addition, exemplary systems and methods are also described further below.

III. Object Storage Modules

The modular object storage devices of the invention include at least one object storage module. Typically, object storage devices include multiple object storage modules. For example, modular object storage device 100 is depicted with eight object storage modules in FIG. 1A. It will be appreciated that the modular object storage devices of the invention can be designed to include essentially any number of object storage modules to tailor the storage capacity and organization of the devices as desired. To further illustrate, however, modular object storage devices typically include between about two and about 100 object storage modules, and still more typically between about four and about 24 object storage modules. In one embodiment, a modular object storage device includes 96 object storage modules.

The object storage modules of the devices described herein each generally include at least one shelf that is structured to support at least one object. In certain embodiments, object storage modules include multiple shelves. Although object storage modules can be designed to include essentially any number of shelves, they typically include between two and about 100 shelves, and still more typically between about nine and about 27 shelves (e.g., about 15 shelves, about 20 shelves, about 25 shelves, etc.). In addition, object storage module shelves can include a wide variety of shapes that are typically selected in view of the shapes of the types of objects to be supported on the shelves. Shelves 104 of modular object storage device 100, which are structured to support standard multi-well plates (e.g., microtiter or microwell plates), have generally rectangular shapes in which segments of shelves 104 that extend from the opening to object storage module 102 are tapered inwards to permit grasping mechanisms of robotic gripping apparatus to grasp plates 106 without contacting shelves 104. Systems that include modular object storage devices and robotic gripping apparatus are described further below.

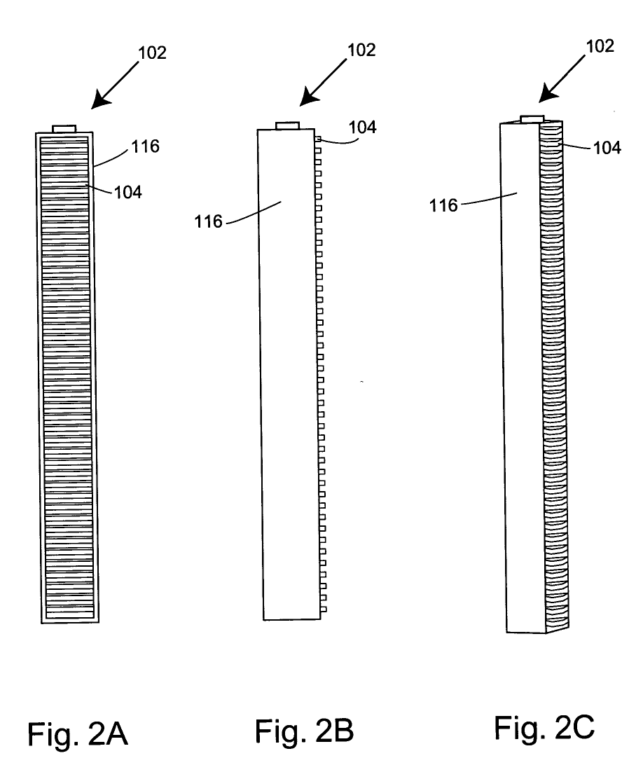

In some embodiments, object storage modules include housings that have multiple, vertically stacked shelves, e.g., in the form of a hotel. To illustrate, FIGS. 2A-C schematically illustrate object storage module 102 from front elevational, side elevational, and perspective views, respectively. As shown, object storage module 102 includes housing 116, which is structured to support and position vertically stacked shelves 104 relative to one another. Object storage module housings and shelves are typically fabricated from metal, certain polymers, and/or other durable materials. Object storage device component fabrication is described further below.

The sets of elevated alignment surfaces and at least portions of the contours of object storage modules (e.g., the housings thereof, etc.) are typically structured to substantially correspond with one another. This permits position adjustment components to move object storage modules into alignment with the elevated alignment surfaces in the object storage module receiving areas of the object storage devices of the invention. A wide variety of object storage module contours are optionally selected, e.g., taking into consideration the shape and dimensions of the objects to be stored in the particular module. Exemplary object storage module contours that can be utilized include shapes, such as regular n-sided polygons, irregular n-sided polygons, triangles, squares, rectangles, trapezoids, circles, ovals, portions thereof, and/or the like. In certain embodiments, for example, the portion of the contour of an object storage module that substantially corresponds to a given set of elevated alignment surfaces forms about a 90° angle (e.g., the object storage module contour comprises a square-, a rectangular-, or a right triangular-shape). As also discussed further below, position adjustment components are typically attached or attachable to object storage modules and support elements in these embodiments of the invention such that the position adjustment components substantially bisect these 90° angles. In these embodiments, this configuration facilitates moving the object storage modules into contact with corresponding elevated alignment surfaces of object storage module receiving areas.

The object storage modules of the storage devices of the invention are optionally structured to store many different types of objects. In some embodiments, for example, object storage module shelves are structured to support containers and/or substrates. Exemplary containers include plates, sample plates, multi-well plates, multi-well dialysis plates, protein crystallography plates, reaction blocks, reaction block carriers, sample holders, petri dishes, test tubes, vials, crucibles, reaction vessels, reaction flasks, centrifuge rotors, fermentation vessels, and/or the like. To further illustrate, standard multi-well plates typically include external dimensions of between about 110 mm and about 150 mm×between about 70 mm and about 110 mm, and more typically between about 120 mm and about 140 mm×between about 80 mm and about 100 mm (e.g., 127.7 mm×85.4 mm). Accordingly, in embodiments where object storage modules are designed to store standard multi-well plates, shelves are fabricated to include at least these dimensions. In certain embodiments, however, shelves are fabricated with dimensions that are sufficient to support more than one multi-well plate or other object per shelf. Exemplary substrates include glass or polymeric slides (e.g., having arrayed probe molecules, etc.), semi conductor wafers, compact disks (CDs), digital video disks (DVDs), membranes, trays, and/or the like.

IV. Support Elements

The modular object storage devices of the invention also include support elements that include one or more object storage module receiving areas that are each typically structured to receive an object storage module. In certain embodiments, however, a particular object storage module receiving area is structured to receive more than one object storage module. To illustrate, support elements typically include between about two and about 100 object storage module receiving areas, and still more typically between about four and about 24 object storage module receiving areas. In one embodiment, a support element includes 96 object storage module receiving areas. In addition, the object storage module receiving areas each typically include at least one set of at least three elevated alignment surfaces that together substantially correspond to at least a portion of a contour of an object storage module. Position adjustment components, which are described further below, are structured to move object storage modules into contact the elevated alignment surfaces to position the object storage modules in desired positions, e.g., accurately aligned relative to object translocation components. In certain embodiments, the positions or locations of support elements are substantially fixed or determined relative to other items, such as object translocation components or the like.

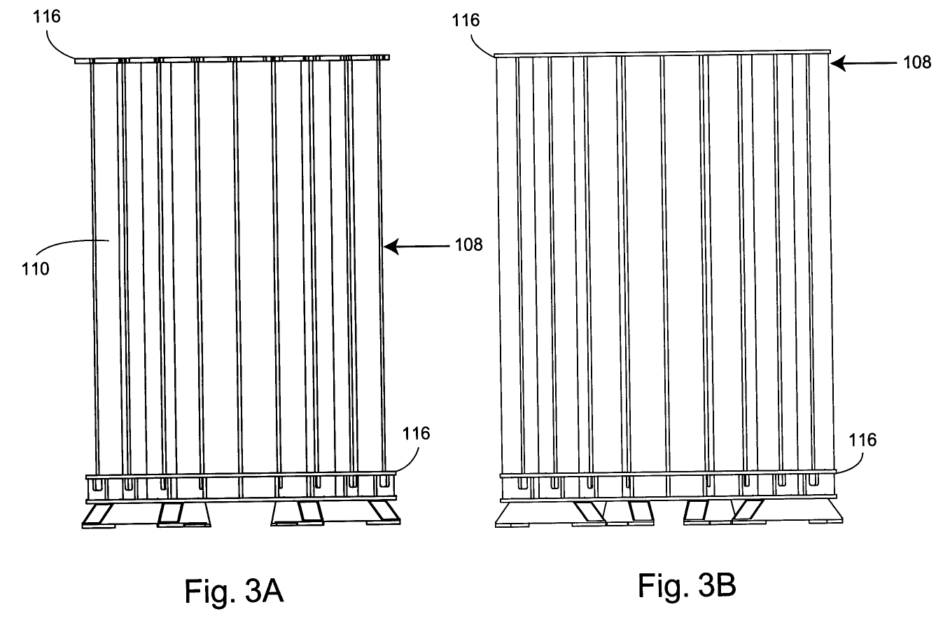

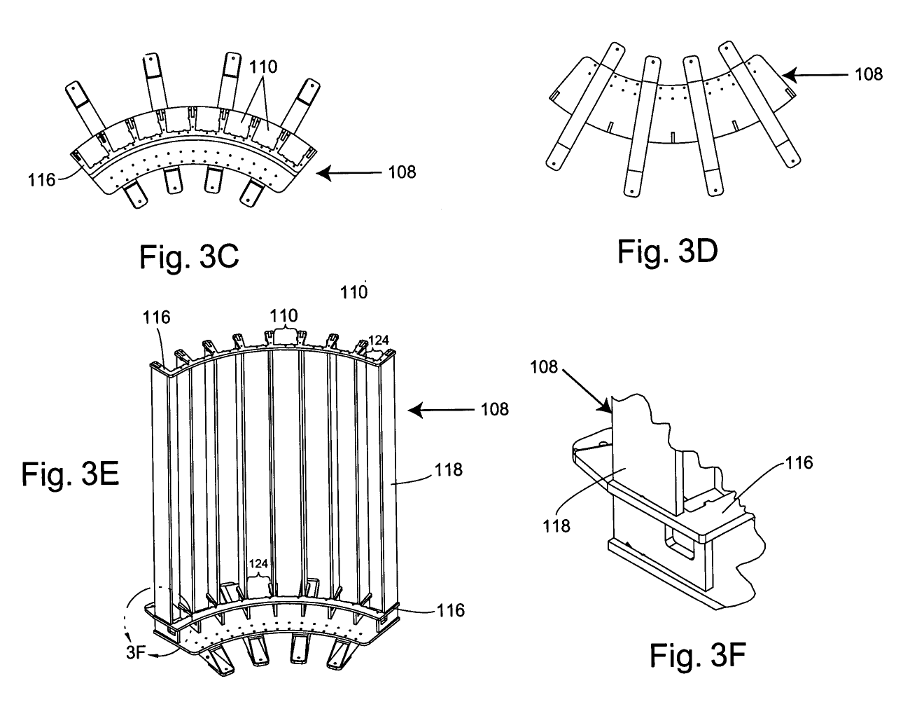

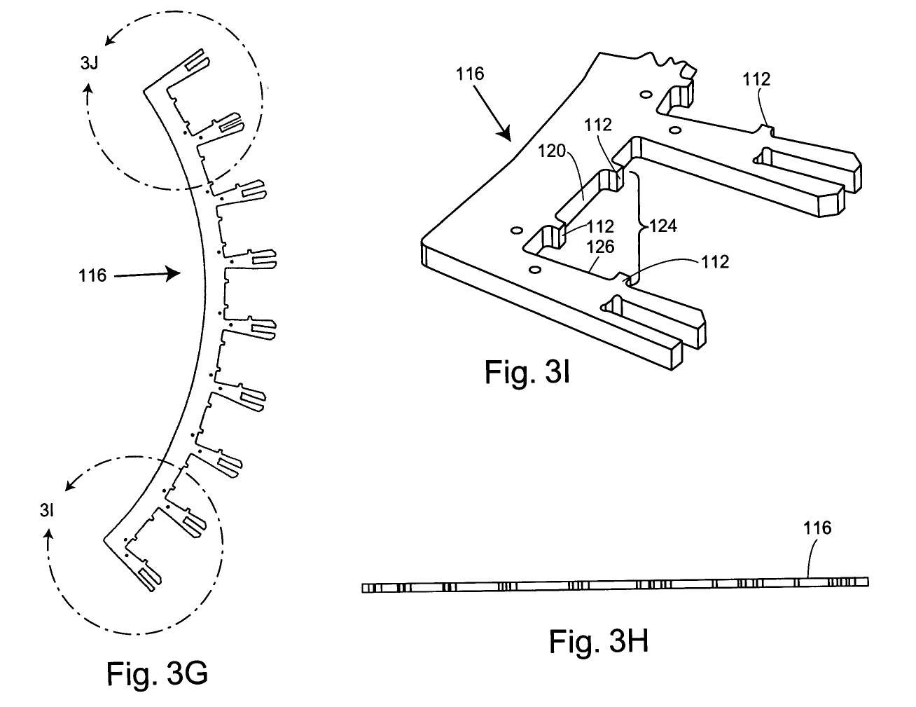

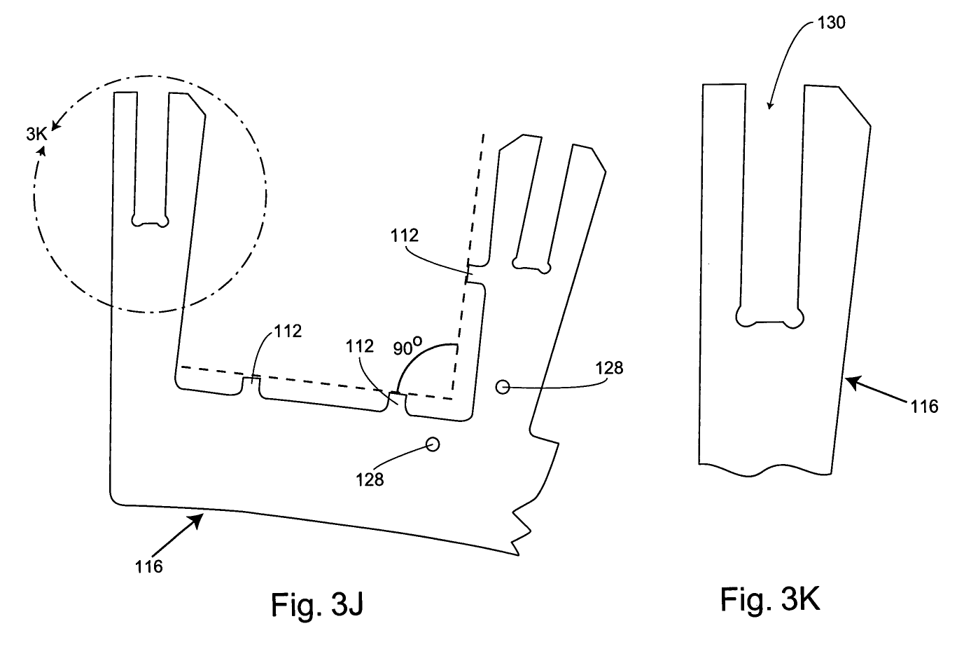

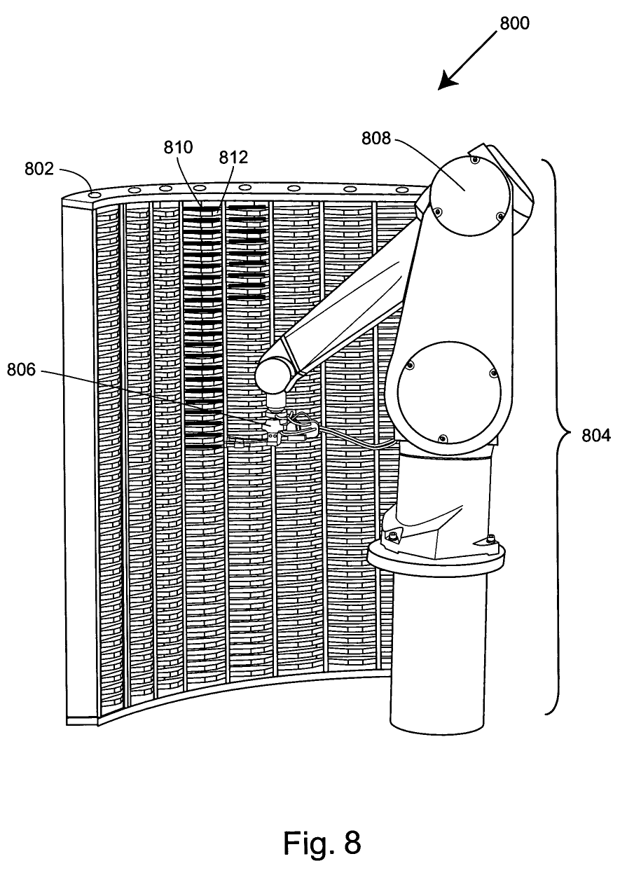

To illustrate, FIGS. 3A-F schematically show support element 108 from different views according to one embodiment of the invention. More specifically, FIGS. 3A-D schematically show curved support element 108 from front elevational, back elevational, top, and bottom views, respectively. When viewed from the front, support element 108 comprises a convex curve. In other embodiments, support elements include concave curves, substantially linear portions, combinations of curve types, or combinations of curved and linear segments. An exemplary concavely curved support element is schematically shown in, e.g., FIG. 8, which is described further below. FIG. 3E schematically depicts support element 108 from a rear perspective view. As shown, support element 108 includes eight object storage module receiving areas 110. In addition, FIG. 3F schematically shows a detailed perspective view of frame component 116 mated with vertical structural component 118 of support element 108. Frame components 116 and vertical structural components 118 define object storage module receiving areas 110. Frame components are also described further below.

To further illustrate, FIGS. 3G-K schematically further depict various aspects of support element 108. For example, FIGS. 3 G and H schematically illustrate frame component 116 of support element 108 from top and front elevational views, respectively. Support element 108 includes two frame components 116, which partially define object storage module receiving areas 110 of modular object storage device 100. In some embodiments, the modular object storage devices of the invention include only a single frame component, whereas in others, more than two are utilized. Typically, two or more frame components are included in a support element, e.g., to provide added stability to the alignment of object storage modules positioned in object storage module receiving areas.

Elevated alignment surfaces are generally disposed on, or extend from, one or more surfaces of object storage module receiving areas to determine the positions of object storage modules along at least two translational axes when the object storage modules are moved into contact with the elevated alignment surfaces. Optionally, elevated alignment surfaces are disposed such that they determine the positions of objects along all three translational axes when the object storage modules are moved into contact with the elevated alignment surfaces. In some embodiments, for example, object storage module receiving areas include at least two sides in which a first side includes at least two elevated alignment surfaces of a set, and a second side includes at least one elevated alignment surface of the set. For example, FIG. 3I schematically depicts a detailed perspective view of a portion of frame component 116. As shown, first side 120 of frame component 116 includes two elevated alignment surfaces 112 (shown as datum pads) of set 124, and second side 126 of, frame component 116 includes one elevated alignment surface 112 of set 124. Typically, object storage module receiving areas include multiple sets of at least three elevated alignment surfaces. This is schematically depicted, for example, in FIG. 3E, which shows support element 108 including two frame components 116. Object storage module receiving area 110 of support element 108 is defined, in part, by corresponding portions of the two frame components 116, which each comprise set 124 of three elevated alignment surfaces. Optionally, more than two sets of elevated alignment surfaces are included in a given object storage module receiving area (e.g., 3, 4, 5, 6, 7, or more sets of elevated alignment surfaces). In some of these embodiments, for example, support elements include more than two frame components comprising the sets of elevated alignment surfaces. In certain embodiments, members of individual sets of elevated alignment surfaces are disposed on more than two sides of a given object storage module receiving area or portion thereof.

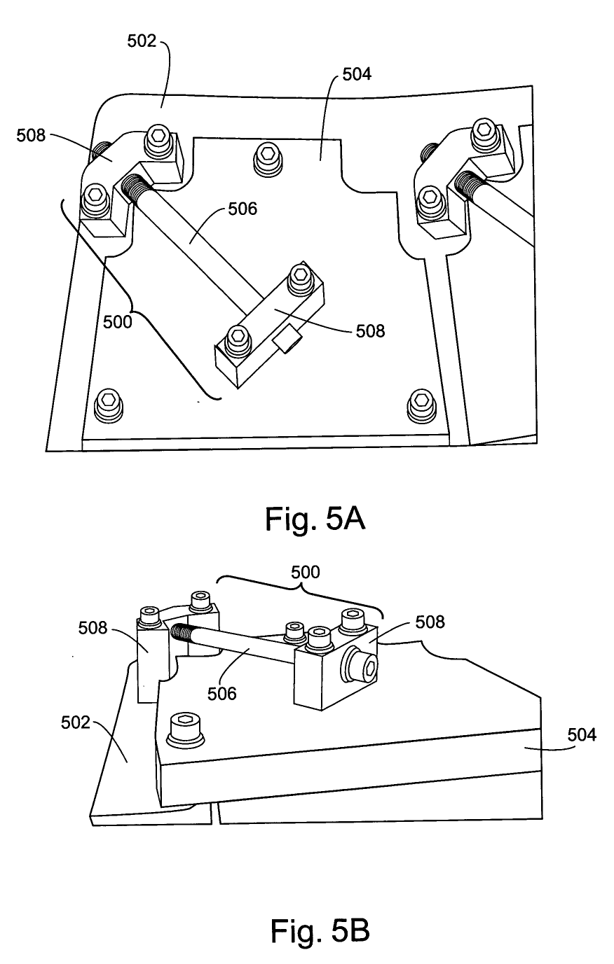

As referred to above, members of sets of elevated alignment surfaces together typically substantially correspond to at least a portion of the contour of an object storage module. Exemplary object storage module contours are described further above. In certain embodiments, the portion of the contour of a particular object storage module that contacts a set of elevated alignment surfaces forms about a 90° angle in an assembled modular object storage device. Accordingly, the elevated alignment surfaces in the set together also form about a 90° angle such that the set substantially corresponds to that portion of the object storage module contour in these embodiments. This is schematically depicted in, e.g., FIG. 3J which shows a detailed top view of a portion of frame component 116. In these embodiments, at least portions of a position adjustment component are typically attached to object storage module 102 and support element 108 (e.g., via holes 128 of frame component 116) such that the position adjustment component substantially bisects the 90° angle. This is also illustrated in, e.g., FIG. 5A, which is described further below.

To further illustrate features of the invention, FIG. 3K schematically depicts a detailed top view of a segment of the frame component portion of FIG. 3J. More specifically, this frame component portion of frame component 116 includes notch 130 into which a portion of vertical structural component 118 is inserted in an assembled support element 108.

The elevated alignment surfaces included in the object storage module receiving areas of the devices described herein have various embodiments. For example, although other distances are optionally utilized, elevated alignment surfaces are typically elevated relative to, or extend from, at least a portion of at least one other surface of a device by about 5-cm or less, more typically by about 3 cm or less, and still more typically by about 1 cm or less. In addition, individual elevated alignment surfaces in a given set are optionally elevated different distances from one another, e.g., so that together they substantially correspond to an object storage module having a varied contour. Moreover, when an object storage module receiving area includes multiple sets of elevated alignment surfaces, different sets may also be elevated different distances in the object storage module receiving area according to the contour of the particular object storage module to be received by that object storage module receiving area. Furthermore, individual sets of elevated alignment surfaces optionally include more than three members, e.g., 4, 5, 6, or more elevated alignment surfaces in some embodiments of the invention.

Elevated alignment surfaces can also have essentially any shape. In certain embodiments, for example, a particular elevated alignment surface may have a shape selected from, e.g., a regular n-sided polygon, an irregular n-sided polygon, a triangle, a square, a rectangle, a trapezoid, a circle, an oval, and/or the like. These shapes can be fabricated using many different techniques and materials. For example, elevated alignment surfaces include metal, wood, or polymeric surfaces in some embodiments. In certain embodiments, elevated alignment surfaces are fabricated as substantially flat or planar surfaces. Optionally, elevated alignment surfaces are further processed by, e.g., applying elastomeric materials to the surfaces prior to use to prevent damage to object storage modules upon contacting the elevated alignment surfaces. Certain fabrication methods that are optionally utilized are illustrated further below.

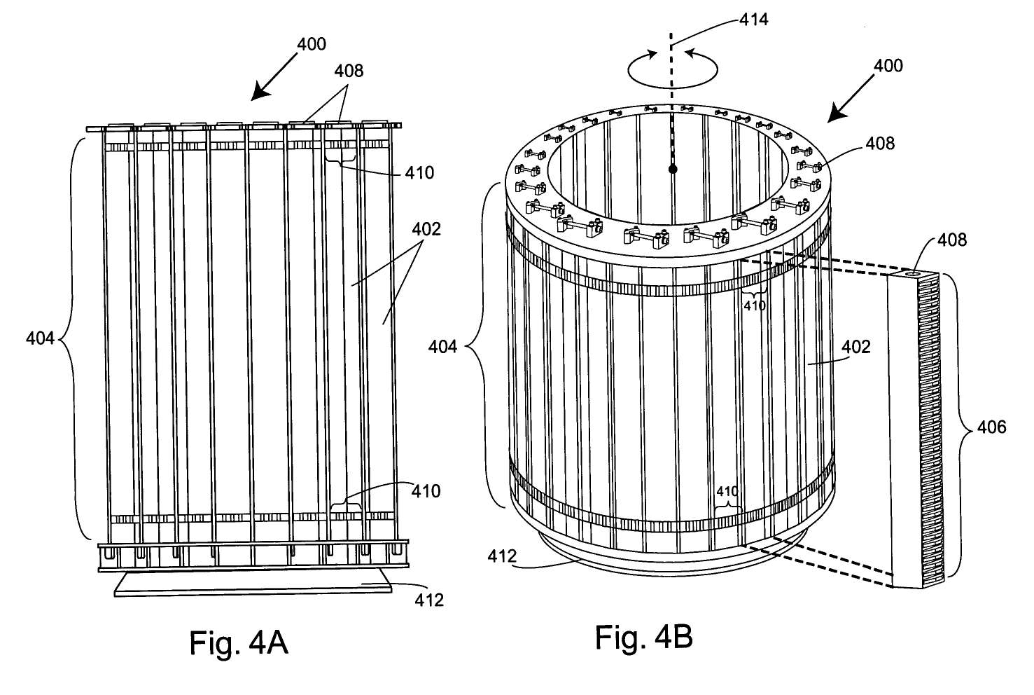

To illustrate other features of the invention, FIGS. 4 A and B schematically show selectively rotatable support element 400 from side elevational and partially exploded perspective views, respectively, according to one embodiment. As shown, support element 400 includes multiple object storage module receiving areas 402 formed in frame structure 404. Object storage module receiving areas 402 are structured to receive object storage modules 406. Position adjustment components 408 move object storage module 406 into contact with sets of elevated alignment surfaces 410 included in object storage module receiving areas 402 to position object storage module 406. In addition, support element 400 includes base structure 412 rotatably attached to frame structure 404 such that frame structure 404 selectively rotates about rotational axis 414. In certain embodiments, the rotatable support elements of the invention are manually rotatable, whereas in others, they include operably connected drive mechanisms (e.g., servo motors, stepper motors, etc.) that effect the rotation of these support elements. In some of the latter embodiments, drive mechanisms are coupled to controllers that effect the selective automated rotations of these elements.

V. Position Adjustment Components

The modular object storage devices of the invention also include position adjustment components that are attached or attachable to object storage modules and support elements. Position adjustment components are typically structured to move object storage modules into contact with elevated alignment surfaces to position or locate the object storage module in desired positions, such as accurately aligned relative to an automated object translocation component. When position adjustment components move object storage modules into contact with elevated alignment surfaces, the positions of the object storage modules are typically thereby determined along at least two translational axes. In addition, position adjustment components generally include the ability to apply sufficient force to modify (e.g., reduce, compensate for, etc.) object storage module structural defects, such as off-axis twists or other imperfections in the structure of object storage modules when the position adjustment components move or align the object storage modules relative to the support element.

The position adjustment components utilized in the devices described herein include many different embodiments. To illustrate, FIGS. 5 A and B schematically illustrate position adjustment component 500 connected to frame component 502 (partial view) and object storage module 504 (partial view) via male fastening element 506 and female fastening elements 508 from top and side perspective views, respectively, according to one embodiment of the invention. As shown, object storage module 504 and frame component 502 of a support element each include one female fastening element 508. Holes are disposed through female fastening elements 508. As also shown, the holes are structured to receive male fastening element 506 to effect contact between object storage module 504 and the elevated alignment surfaces (not within view) of frame component 502 when male fastening element 506 is disposed in the holes. In the embodiment shown, male fastening element 506 is a bolt, and the hole disposed through female fastening element 508 disposed on frame component 502 includes threads that correspond to the threads disposed on the bolt. In the embodiment shown in FIGS. 5 A and B position adjustment component 500 is oriented such that it substantially bisects a 90° angle formed by elevated alignment surfaces (not within view) of frame component 502. FIG. 3J, which is described above, shows an embodiment in which a set of elevated alignment surfaces of a frame component form such a 90° angle. Other position adjustment component orientations are also optionally utilized. Position adjustment component 500 is typically manually operated.

Although position adjustment component 500 includes two female fastening elements and one male fastening element, other configurations are also optionally utilized. For example, two or more female fastening elements can be included on a object storage module, e.g., to further guide and/or provide additional stability to, e.g., the bolt as it is threaded into the female fastening element included on the frame component. In certain embodiments, female fastening elements include multiple holes disposed at least partially through the female fastening elements to accommodate more than one male fastening element at the same time, e.g., to also provide greater stability to the positioning of object storage modules. In addition, male fastening elements can have an orientation opposite to that depicted in, e.g., FIG. 5A, in which male fastening element 506 threads into female fastening element 508 included on object storage module 504.

To further illustrate, the modular object storage devices of the invention can include various numbers of position adjustment components that are attached or attachable to a given object storage module. In some embodiments, for example, a single position adjustment component is attached or attachable to a top or bottom surface of each object storage module in a particular device. In other embodiments, more than one position adjustment components is attached or attachable to a particular object storage module. For example, one or more position adjustment components are optionally attached or attachable to, e.g., both a top and bottom surface of a given object storage module.

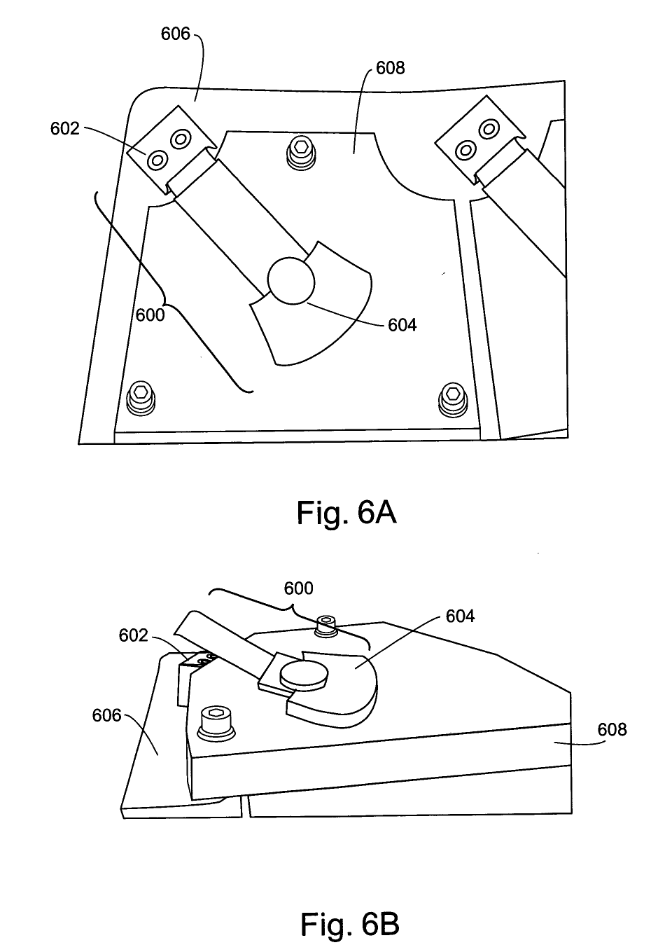

To further illustrate other position adjustment component embodiments, FIGS. 6 A and B schematically depict position adjustment component 600, which includes keeper plate 602 and latch body 604 from top and side perspective views. A shown, keeper plate 602 is connected to frame component 606 and latch body 604 is connected to object storage module 608. Optionally, keeper plates and latch bodies have an opposite orientation in these embodiments in which latch bodies are connected to frame components and keeper plates are connected to object storage modules. Position adjustment component 600 is typically manually operated. Keeper plates and latch bodies that can be adapted for use as position adjustment components are also optionally acquired from various commercial suppliers including, e.g., Southco, Inc. (Concordville, Pa., USA).

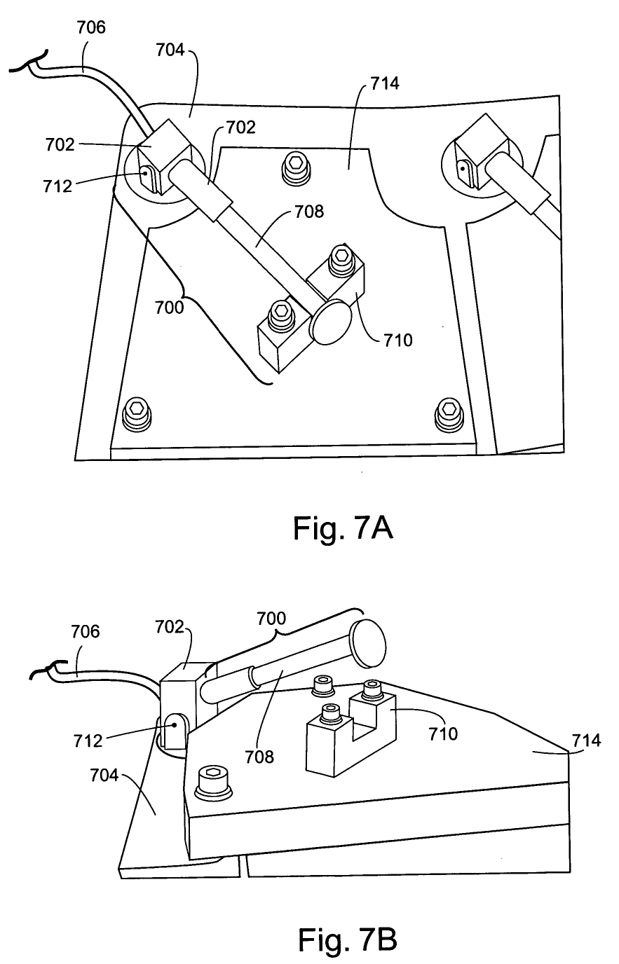

In certain embodiments, position adjustment components are at least partially automated. For example, FIGS. 7 A and B schematically depict automated position adjustment component 700 from top and side perspective views according to one embodiment of the invention. As shown, automated position adjustment component 700 includes pneumatic piston 702 pivotally connected to frame component 704. Pneumatic piston 702 is operably connected to a pressure source, such as an air compressor, a pump, or the like, via conduit 706. The pressure source is generally configured to apply negative and/or positive pressure through conduit 706 to effect the actuation of piston arm 708 such that piston arm 708 engages or disengages bracket 710, which is structured to receive piston arm 708. Typically, the pressure source is also coupled to a controller that regulates the operation of the pressure source. Controllers are described further below. Pneumatic piston 702 is optionally an air piston/cylinder or another functionally equivalent device. In certain embodiments, piston arms are hydraulically or electrically actuated by, e.g., hydraulic pumps, electric motors, or the like operably connected to the piston arms. In some embodiments, a driven mechanism (e.g., a pneumatic, hydraulic, or electrical drive mechanism) is coupled to pneumatic piston 702 to effect rotation of pneumatic piston 702 about pivot point 712 into or out of contact with bracket 710. These drive mechanisms are also typically coupled to a controller, which regulates their operation. As also shown, object storage module 714 includes bracket 710. During operation, piston arm 708 is typically pivoted into contact with bracket 710 and the pressure source is engaged such that piston arm 708 moves object storage module 714 into contact with the elevated alignment surfaces of a object storage module receiving area via bracket 710. As with the other illustrative position adjustment components described herein, the relative orientation and positioning of pneumatic piston 702 and bracket 710 can also be varied.

V. Object Storage Device Component Fabrication

Device components or portions thereof (e.g., object storage modules, housings, shelves, support elements, frame components, position adjustment components, etc.) are optionally formed by various fabrication techniques or combinations of such techniques including, e.g., milling, machining, welding, stamping, engraving, injection molding, cast molding, embossing, extrusion, etching (e.g., electrochemical etching, etc.), or other techniques. These and other suitable fabrication techniques are generally known in the art and described in, e.g., Altintas, Manufacturing Automation: Metal Cutting Mechanics, Machine Tool Vibrations, and CNC Design, Cambridge University Press (2000), Molinari et al. (Eds.), Metal Cutting and High Speed Machining, Kluwer Academic Publishers (2002), Stephenson et al., Metal Cutting Theory and Practice, Marcel Dekker (1997), Rosato, Injection Molding Handbook, 3^{rd} Ed., Kluwer Academic Publishers (2000), Fundamentals of Injection Molding, W. J. T. Associates (2000), Whelan, Injection Molding of Thermoplastics Materials, Vol. 2, Chapman & Hall (1991), Fisher, Extrusion of Plastics, Halsted Press (1976), and Chung, Extrusion of Polymers: Theory and Practice, Hanser-Gardner Publications (2000), which are each incorporated by reference. In certain embodiments, following fabrication, device components or portions thereof are optionally further processed, e.g., by coating surfaces with a hydrophilic coating, a hydrophobic coating (e.g., a Xylan 1010DF/870 Black coating available from Whitford Corporation (West Chester, Pa., USA), epoxy powder coatings available from DuPont Powder Coatings USA, Inc. (Houston, Tex., USA)), or the like, e.g., to prevent interactions between component surfaces and reagents, samples, or the like, to provide a desired appearance, and/or the like.

The devices of the invention are typically assembled from individually fabricated component parts (e.g., shelves, housings, frame components, vertical structural components, etc). Device fabrication materials are generally selected according to properties, such as durability, expense, or the like. In certain embodiments, devices or components thereof, are fabricated from various metallic materials, such as stainless steel, anodized aluminum, or the like. Optionally, device components are fabricated from polymeric materials such as, polytetrafluoroethylene (TEFLON™), polypropylene, polystyrene, polysulfone, polyethylene, polymethylpentene, polydimethylsiloxane (PDMS), polycarbonate, polyvinylchloride (PVC), polymethylmethacrylate (PMMA), or the like. Component parts are also optionally fabricated from other materials including, e.g., wood, glass, silicon, or the like. In addition, components parts are typically welded, bonded, bolted, riveted, etc. to one another to form, e.g., an object storage module, a support structure, or the like.

VI. Systems

The invention also provides systems that include the modular object storage devices described herein. These systems can be used, e.g., to store and manage large numbers of objects, such as compound libraries stored in multi-well containers with high throughput. The systems of the invention also include object translocation components, such as robotic gripping apparatus that are configured to translocate one or more objects (e.g., multi-well plates, substrates, etc.) to and/or from object storage module shelves, and/or object storage modules to and/or from object storage module receiving areas of support elements of modular object storage devices. In some embodiments, the systems of the invention also include controllers, thermal modulation components (e.g., incubators, freezers, refrigerators, etc.), material transfer components (e.g., fluid handlers or the like), and/or detection components. Optionally, the systems of the invention or components thereof are housed within enclosures, e.g., to prevent the contamination of objects stored on the shelves of modular object storage devices, or the like.

To illustrate, FIG. 8 schematically illustrates system 800, which includes modular object storage device 802 and robotic gripping apparatus 804 from a perspective view according to one embodiment of the invention. As shown, robotic gripping apparatus 804 includes gripper mechanism 806 operably connected to boom 808, which positions gripper mechanism 806 relative to multi-well plates 810 such that multi-well plates 810 can be grasped by gripper mechanism 806 and translocated to and/or from shelves 812 of modular object storage device 802 by boom 808. Typically, robotic gripping apparatus 804 translocates multi-well plates 810 between modular object storage device 802 and another system component, such as a material transfer component, a detection component, or other work stations, e.g., for processing or analysis.

A variety of available robotic elements (robotic arms, movable platforms, etc.) can be used or modified for use with these systems as object translocation components. Typically, these robotic elements are operably connected to controllers that control their movement and other functions. Controllers are described further below. Exemplary robotic gripping devices that are optionally adapted for use in the systems of the invention are described further in, e.g., U.S. Pat. No. 6,592,324, entitled “GRIPPER MECHANISM,” issued Jul. 15, 2003 to Downs et al., and International Publication No. WO 02/068157, entitled “GRIPPING MECHANISMS, APPARATUS, AND METHODS,” filed Feb. 26, 2002 by Downs et al., which are both incorporated by reference.

The controllers of the automated systems of the present invention are typically operably connected to and configured to effect or control operation of one or more components of the system, such as object translocation components, automated position adjustment components, thermal modulation components, material transfer components, detection components, and/or the like. More specifically, controllers are generally included either as separate or integral system components that are utilized, e.g., to effect the translocation of object, the movement of automated position adjustment components, the modulation of system temperatures, the transfer of materials to and/or from containers or substrates, the detection and/or analysis of detectable signals received from containers or substrates by detectors, etc. Controllers and/or other system components is/are optionally coupled to an appropriately programmed processor, computer, digital device, or other logic device or information appliance (e.g., including an analog to digital or digital to analog converter as needed), which functions to instruct the operation of these instruments in accordance with preprogrammed or user input instructions (e.g., object locations in object storage modules, temperature settings, volumes of fluid to be transferred, etc.), receive data and information from these instruments, and interpret, manipulate and report this information to the user.

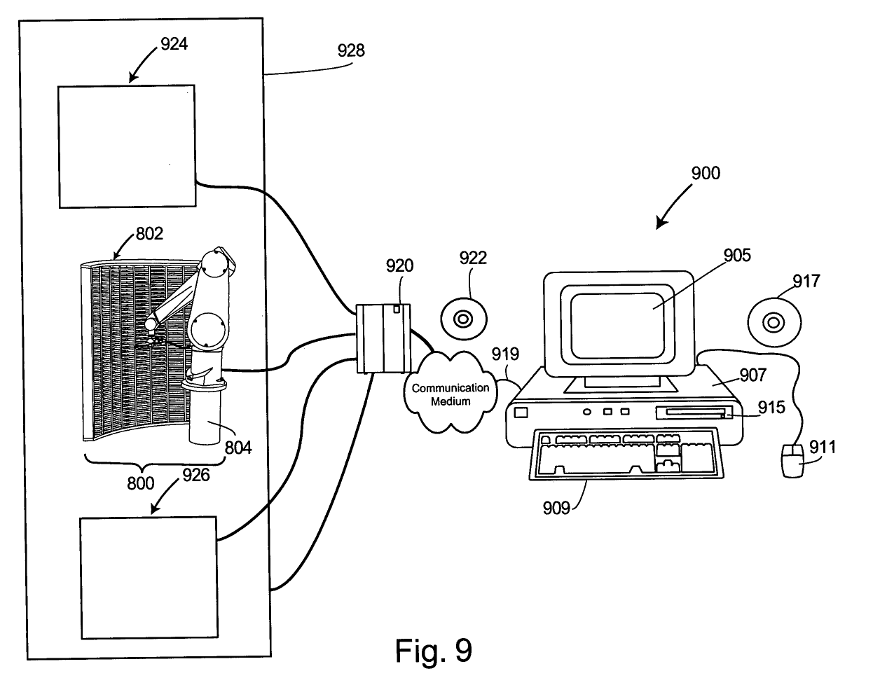

A controller or computer optionally includes a monitor, which is often a cathode ray tube (“CRT”) display, a flat panel display (e.g., active matrix liquid crystal display, liquid crystal display, etc.), or others. Computer circuitry is often placed in a box, which includes numerous integrated circuit chips, such as a microprocessor, memory, interface circuits, and others. The box also optionally includes a hard disk drive, a floppy disk drive, a high capacity removable drive such as a writeable CD-ROM, and other common peripheral elements. Inputting devices such as a keyboard or mouse optionally provide for input from a user. An exemplary system comprising a computer is schematically illustrated in FIG. 9.

The computer typically includes appropriate software for receiving user instructions, either in the form of user input into a set of parameter fields, e.g., in a GUI, or in the form of preprogrammed instructions, e.g., preprogrammed for a variety of different specific operations. The software then converts these instructions to an appropriate language for instructing the operation of one or more controllers to carry out the desired operation, e.g., varying or selecting the rate or mode of movement of various system components, modulating system temperatures, or the like. The computer then receives the data from, e.g., sensors/detectors included within the system (e.g., bar code readers that detect bar codes disposed on objects, etc.), and interprets the data, either provides it in a user understood format, or uses that data to initiate further controller instructions, in accordance with the programming, e.g., such as in monitoring detectable signal intensity, object storage module and/or object positioning, or the like.

More specifically, the software utilized to control the operation of the systems of the invention typically includes logic instructions that direct, e.g., the system to convey material (e.g., fluidic material) to containers or substrates, automated position adjustment components to move object storage modules into contact with elevated alignment surfaces, a robotic gripping apparatus to translocate containers or substrates, and/or the like.

The computer can be, e.g., a PC (Intel x86 or Pentium chip-compatible DOS™, OS2™, WINDOWS™, WINDOWS NT™, WINDOWS95™, WINDOWS98™, WINDOWS2000™, WINDOWS XP™, LINUX-based machine, a MACINTOSH™, Power PC, or a UNIX-based (e.g., SUN™ work station) machine) or other common commercially available computer, which is known to one of skill in the art. Standard desktop applications such as word processing software (e.g., Microsoft Word™ or Corel WordPerfect™) and database software (e.g., spreadsheet software such as Microsoft Excel™, Corel Quattro Pro™, or database programs such as Microsoft Access™ or Paradox™) can be adapted to the present invention. Software for performing, e.g., material conveyance to selected wells of a multi-well plate, assay detection, and data deconvolution is optionally constructed by one of skill using a standard programming language such as Visual basic, Perl, C, C++, Fortran, Basic, Java, or the like.

In certain embodiments, the systems of the invention include at least one thermal modulation component that is configured to modulate a temperature in and/or proximal to other components of the system. For example, thermal modulation components are typically configured to regulate the temperature of objects stored on the shelves of the modular storage devices described herein. To further illustrate, thermal modulation components optionally include freezers, refrigerator, incubators, or the like that can be used to selectively modulate temperature as desired. In certain embodiments, at least a portion of at least one of the components of the system is housed in the thermal modulation component. In some embodiments, for example, only modular storage devices are enclosed or otherwise housed within thermal modulation components. In other embodiments, other system components, such as object translocation components are also housed within thermal modulation components. Many different thermal modulation components are known in the art and can be adapted for use in the systems of the present invention. For example, incubation devices that are optionally adapted for use with the systems of the present invention are described in, e.g., International Publication No. WO 03/008103, entitled “HIGH THROUGHPUT INCUBATION DEVICES,” filed Jul. 18, 2002 by Weselak et al., which is incorporated by reference.

The systems of the invention optionally include material transfer components, such as multi-channel pipetting devices that are configured to transfer materials (e.g., fluidic materials, such as reagents, samples, or the like) to and/or from objects, such as substrates or multi-well containers. Exemplary material transfer components that may be adapted for use in the systems of the invention are also described in, e.g., U.S. Pat. No. 6,569,687, entitled “DUAL MANIFOLD SYSTEM AND METHOD FOR FLUID TRANSFER,” issued May 27, 2003 to Doktycz et al., and U.S. Pat. Appl. Publication No. U.S. 2003/0170903, entitled “HIGH PERFORMANCE LOW VOLUME, NON-CONTACT LIQUID DISPENSING APPARATUS AND METHOD,” published Sep. 11, 2003 by Johnson et al., which are both incorporated by reference.

In certain embodiments, the systems of the invention also include at least one detection component that is configured to detect one or more detectable signals produced by one or more materials disposed in and/or taken from one or more objects, e.g., the wells of multi-well containers, the surfaces of substrates, or the like. Suitable signal detectors that are optionally utilized in these systems detect, e.g., fluorescence, phosphorescence, radioactivity, mass, concentration, pH, charge, absorbance, refractive index, luminescence, temperature, magnetism, or the like. Detectors optionally monitor one or a plurality of signals from upstream and/or downstream of the performance of, e.g., a given processing or assay step. For example, the detector optionally monitors a plurality of optical signals, which correspond in position to “real time” results. Example detectors or sensors include imaging systems (e.g., for protein crystal imaging, etc.), photomultiplier tubes, CCD arrays, optical sensors, temperature sensors, pressure sensors, pH sensors, conductivity sensors, scanning detectors, or the like. Each of these as well as other types of sensors are optionally readily incorporated into the systems described herein. The detector optionally moves relative to multi-well containers, substrates, or other assay components, or alternatively, multi-well containers, substrates, or other assay components move relative to the detector. In certain embodiments, for example, detection components are coupled to translation components that move the detection components relative to multi-well containers positioned on positioning components of the systems described herein. Optionally, the systems of the present invention include multiple detectors. In these systems, such detectors are typically placed either in or adjacent to, e.g., a multi-well container or other vessel, or substrate, such that the detector is within sensory communication with the multi-well container or other vessel (i.e., the detector is capable of detecting the property of the container or vessel or portion thereof, the contents of a portion of the container or vessel, or the like, for which that detector is intended).

The detector optionally includes or is operably linked to a computer, e.g., which has system software for converting detector signal information into assay result information or the like. For example, detectors optionally exist as separate units, or are integrated with controllers into a single instrument. Integration of these functions into a single unit facilitates connection of these instruments with the computer, by permitting the use of few or a single communication port for transmitting information between system components. Computers and controllers are described further above. Detection components that are optionally included in the systems of the invention are described further in, e.g., Skoog et al., Principles of Instrumental Analysis, 5^{th} Ed., Harcourt Brace College Publishers (1998) and Currell, Analytical Instrumentation: Performance Characteristics and Quality, John Wiley & Sons, Inc. (2000), which are both incorporated by reference.

FIG. 9 is a block diagram showing a representative logic device in which various aspects of the invention may be embodied. As will be understood by practitioners in the art from the teachings provided herein, the invention is optionally implemented in hardware and software. In some embodiments, different aspects of the invention are implemented in either client-side logic or server-side logic. As will also be understood in the art, the invention or components thereof may be embodied in a media program component (e.g., a fixed media component) containing logic instructions and/or data that, when loaded into an appropriately configured computing device, cause that apparatus or system to perform according to the invention. As will additionally be understood in the art, a fixed media containing logic instructions may be delivered to a viewer on a fixed media for physically loading into a viewer's computer or a fixed media containing logic instructions may reside on a remote server that a viewer accesses through a communication medium in order to download a program component.

FIG. 9 shows information appliance or digital device 900 that may be understood as a logical apparatus (e.g., a computer, etc.) that can read instructions from media 917 and/or network port 919, which can optionally be connected to server 920 having fixed media 922. Information appliance 900 can thereafter use those instructions to direct server or client logic, as understood in the art, to embody aspects of the invention. One type of logical apparatus that may embody the invention is a computer system as illustrated in 900, containing CPU 907, optional input devices 909 and 911, disk drives 915 and optional monitor 905. Fixed media 917, or fixed media 922 over port 919, may be used to program such a system and may represent a disk-type optical or magnetic media, magnetic tape, solid state dynamic or static memory, or the like. In specific embodiments, the aspects of the invention may be embodied in whole or in part as software recorded on this fixed media. Communication port 919 may also be used to initially receive instructions that are used to program such a system and may represent any type of communication connection. Optionally, aspects of the invention are embodied in whole or in part within the circuitry of an application specific integrated circuit (ACIS) or a programmable logic device (PLD). In such a case, aspects of the invention may be embodied in a computer understandable descriptor language, which may be used to create an ASIC, or PLD.

FIG. 9 also includes system 800, which as described above, includes modular object storage device 802 and robotic gripping apparatus 804. Robotic gripping apparatus 804 is operably connected to information appliance 900 via server 920. Optionally, system 800 is directly connected to information appliance 900. During operation, robotic gripping apparatus 804 translocates multi-well containers, substrates, or other objects to and/or from selected shelves of modular object storage device 802, e.g., as part of an assay or other process. FIG. 9 also shows detection component 924, which is optionally included in the systems of the invention. As shown, detection component 924 is operably connected to information appliance 900 via server 920. In some embodiments, detection component 924 is directly connected to information appliance 900. In certain embodiments, detection component 924 is configured to detect detectable signals produced in the wells of multi-well containers or on substrate surfaces. In these embodiments, robotic gripping apparatus 804 typically translocates selected multi-well containers or substrates proximal to detection component 924 to effect detection. As also shown, material transfer component 926 is operably connected to information appliance 900 via server 920. As with the other system components, material transfer component 926 is optionally directly connected to information appliance 900. During operation, robotic gripping apparatus 804 optionally translocates, e.g., multi-well containers or substrates to material transfer component 926 so that materials (e.g., fluidic materials, etc.) can be transferred to and/or from the multi-well containers or substrates. In the embodiment shown, system 800, detection component 924, and material transfer component 926 are enclosed within thermal modulation component 928, which is operably connected to information appliance 900 via server 920. Optionally, thermal modulation component 928 is directly connected to information appliance 900. Thermal modulation component 928 modulates the temperatures of, e.g., multi-well containers or substrates.

VII. Methods of Positioning Object Storage Modules

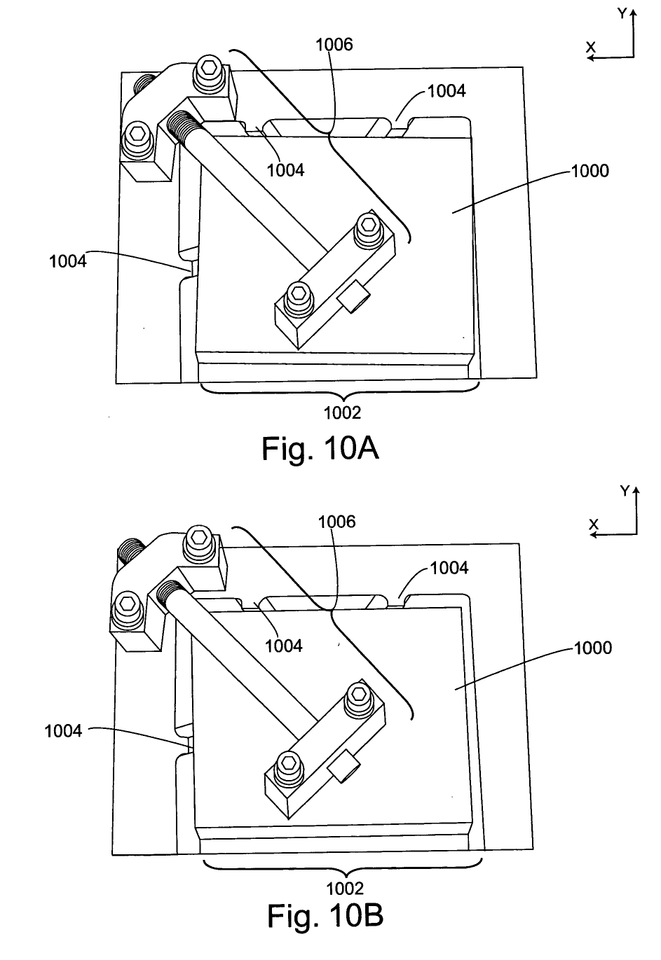

The invention also provides methods of positioning object storage modules. The methods generally include moving object storage modules into contact with elevated alignment surfaces, as described herein, using a position adjustment component. To illustrate, FIG. 10A schematically depicts object storage module 1000 located in object storage module receiving area 1002 such that its X- and Y-translational axes have not been determined by contacting elevated alignment surfaces 1004. As schematically illustrated in FIG. 10B, object storage module 1000 has been moved into contact with elevated alignment surfaces 1004 of object storage module receiving area 1002 by position adjustment component 1006 to determine the X- and Y-translational axes of object storage module 1000 relative to object storage module receiving area 1002.

While the foregoing invention has been described in some detail for purposes of clarity and understanding, it will be clear to one skilled in the art from a reading of this disclosure that various changes in form and detail can be made without departing from the true scope of the invention. For example, all the techniques and apparatus described above can be used in various combinations. All publications, patents, patent applications, and/or other documents cited in this application are incorporated by reference in their entirety for all purposes to the same extent as if each individual publication, patent, patent application, and/or other document were individually indicated to be incorporated by reference for all purposes.

What is claimed is:

1. A modular object storage device, comprising:
at least one object storage module comprising at least one shelf that is structured to support at least one object;
a support element comprising at least one object storage module receiving area that is structured to receive the object storage module, which object storage module receiving area comprises at least one set of at least three elevated alignment surfaces that together substantially correspond to at least a portion of a contour of the object storage module; and,
at least one position adjustment component that is attached or attachable to the object storage module and the support element, which position adjustment component is structured to move the object storage module into contact with each of the elevated alignment surfaces, thereby positioning the object storage module in a desired position.

2. The modular object storage device of claim 1, wherein the object storage module receiving area comprises at least two sides, wherein a first side comprises at least two elevated alignment surfaces of the set, and a second side comprises at least one elevated alignment surface of the set.

3. The modular object storage device of claim 1, wherein the object storage module comprises a housing having multiple, vertically stacked shelves.

4. The modular object storage device of claim 1, wherein the contour of the object storage module comprises a shape selected from the group consisting of: a regular n-sided polygon, an irregular n-sided polygon, a triangle, a square, a rectangle, a trapezoid, a circle, an oval, and a portion thereof.

5. The modular object storage device of claim 1, wherein the modular object storage device comprises multiple object storage modules.

6. The modular object storage device of claim 1, wherein the support element comprises at least one frame component that at least partially defines the object storage module receiving area.

7. The modular object storage device of claim 1, wherein the support element comprises a curved shape.

8. The modular object storage device of claim 1, wherein the support element is rotatable.

9. The modular object storage device of claim 1, wherein the support element comprises multiple object storage module receiving areas.

10. The modular object storage device of claim 1, wherein the object storage module receiving area comprises multiple sets of at least three elevated alignment surfaces.

11. The modular object storage device of claim 1, wherein the elevated alignment surfaces are disposed on one or more surfaces of the object storage module receiving area.

12. The modular object storage device of claim 1, wherein the elevated alignment surfaces comprise datum pads.

13. The modular object storage device of claim 1, wherein multiple position adjustment components are attached or attachable to the object storage module and the support element.

14. The modular object storage device of claim 1, wherein the position adjustment component is automated.

15. The modular object storage device of claim 1, wherein the position adjustment component is manually operated.

16. The modular object storage device of claim 1, wherein the position adjustment component modifies one or more defects in a structure of the object storage module when the object storage module is aligned relative to the support element.

17. The modular object storage device of claim 1, wherein the position adjustment component comprises at least one keeper plate and at least one latch body.

18. The modular object storage device of claim 1, wherein the portion of the contour of the object storage module that substantially corresponds to the set of elevated alignment surfaces forms about a 90° angle, and wherein the position adjustment component is attached or attachable to the object storage module and the support element such that the position adjustment component substantially bisects the 90° angle.

19. The modular object storage device of claim 1, wherein positions of the object storage module along at least two translational axes are determined when the object storage module is moved into contact with the elevated alignment surfaces.

20. The modular object storage device of claim 1, wherein the shelf is structured to support at least one container and/or at least one substrate.

21. The modular object storage device of claim 20, wherein the container is at least one multi-well plate.

22. The modular object storage device of claim 1, wherein the position adjustment component comprises at least one male fastening element and at least two female fastening elements, wherein the object storage module and the support element each comprise at least one of the female fastening elements, and wherein holes are disposed at least partially through the female fastening elements, which holes are structured to receive the male fastening element to effect contact between the object storage module and the elevated alignment surfaces of the object storage module receiving area when the male fastening element is disposed in the holes.

23. The modular object storage device of claim 22, wherein the male fastening element comprises a bolt, and wherein the hole disposed at least partially through at least one of the female fastening elements comprises threads that correspond to the threads disposed on the bolt.

24. A system, comprising:
at least one modular object storage device that comprises:
at least one object storage module comprising at least one shelf that is structured to support at least one object;
a support element comprising at least one object storage module receiving area that is structured to receive the object storage module, which object storage module receiving area comprises at least one set of at least three elevated alignment surfaces that together substantially correspond to at least a portion of a contour of the object storage module; and
at least one position adjustment component that is attached or attachable to the object storage module and the support element, which position adjustment component is structured to move the object storage module into contact with each of the elevated alignment surfaces to position the object storage module in a desired position; and,
at least one object translocation component that is configured to translocate one or more objects to and/or from the shelf, and/or one or more object storage modules to and/or from one or more object storage module receiving areas of the support element.

25. The system of claim 24, wherein the shelf that is structured to support at least one container and/or at least one substrate.

26. The system of claim 24, wherein the object translocation component is automated.

27. The system of claim 24, wherein the object translocation component comprises at least one robotic gripping apparatus.

28. The system of claim 24, wherein the position adjustment component is automated.

29. The system of claim 24, comprising one or more of:
at least one controller configured to effect operation of one or more components of the system;
at least one thermal modulation component that is configured to modulate a temperature in and/or proximal to at least one other component of the system;
at least one material transfer component that is configured to transfer one or more materials to and/or from one or more objects; or,
at least one detection component that is configured to detect one or more detectable signals produced by one or more materials disposed in and/or taken from one or more objects.

30. The system of claim 29, wherein at least a portion of at least one of the components of the system is housed in the thermal modulation component.

31. A method of positioning an object storage module, the method comprising moving the object storage module into contact with at least three elevated alignment surfaces that together substantially correspond to at least a portion of a contour of the object storage module, which object storage module comprises at least one shelf that is structured to support at least one object, thereby positioning the object storage module.

32. The method of claim 31, comprising translocating one or more objects to and/or from the shelf of the object storage module.
